(19) United States
(12) Patent Application Publication
(10) Pub. No.: US 2023/0077330 A1
(43) Pub. Date: Mar. 16, 2023

(54) SUBSTRATE PROCESSING APPARATUS

(71) Applicant: JUSUNG ENGINEERING CO., LTD., Gwangju-si (KR)

(72) Inventors: ChulJoo HWANG, Gwangju-si (KR); Bu-Il JEON, Seoul (KR); Seong-Hyuk CHOI, Yongin-si (KR)

(21) Appl. No.: 18/050,155

(22) Filed: Oct. 27, 2022

Related U.S. Application Data
(63) Continuation of application No. PCT/KR2021/003684, filed on Mar. 25, 2021.

(30) Foreign Application Priority Data
May 29, 2020 (KR) 10-2020-0064655

(51) Int. Cl. H01J 37/32; C23C 16/455; C23C 16/458

(52) U.S. Cl. CPC H01J 37/32532; C23C 16/45551; C23C 16/4586; H01J 37/32174; H01J 37/3244

(57) ABSTRACT

A substrate processing apparatus includes a process chamber providing a reaction space therein and including a substrate entrance through which a substrate enters or exits, a susceptor disposed inside the process chamber and supporting the substrate, a gas injector disposed on an opposing surface to inject a gas toward the substrate, a valve opening and closing the substrate entrance, and a control electrode formed on the valve. The control electrode is vertically driven.

### CROSS-REFERENCE TO RELATED APPLICATIONS

This application is a continuation of and claims priority to PCT/KR2021/003684 filed on Mar. 25, 2021, which claims priority to Korea Patent Application No. 10-2020-0064655 filed on May 29, 2020, the entireties of which are both hereby incorporated by reference.

### TECHNICAL FIELD

The present disclosure relates to a plasma substrate processing apparatus and, more particularly, to a substrate processing apparatus capable of providing an entire reaction space of a process chamber in a uniform process environment.

### BACKGROUND

A typical substrate processing apparatus may include, for example, a process chamber in which a substrate is processed using plasma, or the like, and a transfer chamber in which a substrate is loaded before processing the substrate and a substrate is unloaded after processing the substrate.

In the case of a process chamber, a slot is formed in one sidewall and a substrate may be loaded or unloaded through the slot. In general, the slot may be opened and closed by a slot valve provided outside the slot or outside the chamber.

When a substrate processing operation is performed, the inside of a process chamber, that is, a reaction space should be maintained in a process environment such as vacuum, or the like. In addition, a uniform process environment should be applied to the entire reaction space.

In general, a reaction space has an opening connected to a slot through which a substrate is loaded or unloaded, and the slot is opened and closed by an external slot valve. Therefore, even when the slot is closed by the external slot valve, an empty space is formed between the slot valve and the opening.

The empty space may be connected to the reaction space. As a result, the reaction space may be asymmetrically formed by the vacant space. It may be difficult for the asymmetric reaction space to establish an overall uniform process environment.

When plasma is generated in the reaction space, it may be difficult to uniformly distribute the plasma in the reaction space due to an effect of the empty space. Accordingly, it may be difficult to uniformly perform etching and deposition on the entire surface of the substrate.

In the case in which a plasma thin film is deposited, thin film uniformity may be affected by various factors such as structural asymmetry of a chamber, temperature non-uniformity of a substrate, a gas flow pattern formed by a pump, plasma non-uniformity, and the like. In particular, local plasma non-uniformity may be affected by the structural asymmetry and electrical characteristics of the chamber and the gas flow pattern formed by the pump.

In plasma processing, local process non-uniformity is also present even when a valve having an internal side surface forming a part of the internal side surface of the chamber is adopted to improve structural azimuthal symmetry. For example, in a valve-free environment, the inside of the chamber is a completely symmetric environment. However, a necessarily required substrate entrance may be disposed to make it difficult to achieve complete symmetry of the chamber. That is, even when the valve provides an internal side surface forming a part of the internal side surface of the chamber, it may be difficult to achieve 100% of symmetry due to an O-ring formed a portion in which the valve and the chamber are in contact with each other. In addition, since electrical characteristics of the valve and electrical characteristics of the chamber are different from each other, RF current does not symmetrically flow in an azimuthal direction, resulting in local process non-uniformity. Accordingly, there is a need for a method capable of controlling local non-uniformity caused by a difference in electrical characteristics.

### SUMMARY

An aspect of the present disclosure is to control local process non-uniformity of a substrate by inserting a control electrode to be adjacent to an internal sidewall of a chamber to apply power to the control electrode.

An aspect of the present disclosure is to provide a uniform process environment in a reaction space by preventing the reaction space from being connected to a slot using a chamber-integrated slot valve when a plasma semiconductor process is performed on a substrate. Nonetheless, remaining local process non-uniformity is controlled using a control electrode formed at an open/close blade of a slot valve.

An aspect of the present disclosure is to symmetrically form a reaction space of a substrate processing apparatus when a semiconductor process is performed on a substrate, and to uniformly perform a process on an entire surface of a substrate by making a plasma process environment uniform in the reaction space.

An aspect of the present disclosure is to control local process non-uniformity of a substrate by inserting a valve, providing an internal side surface forming a part of the internal side surface of the chamber, and connecting the valve to an impedance circuit to change electrical characteristics.

A substrate processing apparatus according to an example embodiment includes a process chamber providing a reaction space therein and including a substrate entrance through which a substrate enters or exits, a susceptor disposed inside the process chamber and supporting the substrate, a gas injector disposed on an opposing surface to inject a gas toward the substrate, a valve opening and closing the substrate entrance, and a control electrode formed on the valve. In an example embodiment, the control electrode may be vertically driven.

In an example embodiment, the valve may include a blade, opening and closing the substrate entrance and having an internal side surface forming a part of the internal side surface of the chamber, and a driving unit allowing the blade to ascend and descend. The control electrode may be formed on the blade.

In an example embodiment, the blade may be grounded or connected to an impedance circuit by a first switch.

In an example embodiment, the impedance circuit may include LC circuits connected to each other in parallel, or LC circuits connected to each other in series. A capacitor constituting the LC circuit may be variable.

In an example embodiment, the control electrode may be connected to a power supply unit.

In an example embodiment, the power supply unit may include at least one of a positive DC power supply, a negative DC power supply, and an RF power supply.

In an example embodiment, the substrate processing apparatus may further include a second switch configured to connect the power supply unit or a ground and the control unit to each other. The second switch may selectively connected to one of the positive DC power supply, the negative DC power supply, and the RF power supply.

A substrate processing apparatus according to an example embodiment includes a process chamber providing a reaction space therein, a susceptor disposed inside the process chamber and supporting a substrate, a gas injector disposed on an opposing surface of the susceptor to inject a gas toward the substrate, and a valve providing an internal side surface forming a part of the internal side surface of the chamber and opening and closing a substrate entrance of the process chamber. The valve includes a blade, opening and closing the substrate entrance and having an internal side surface forming a part of the internal side surface of the chamber, and a driving unit allowing the blade to ascend and descent. The blade is grounded or connected to an impedance circuit by a switch.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1 is a perspective view of a substrate processing apparatus according to an example embodiment of the present disclosure.

FIG. 2 is a cross-sectional view of the substrate processing apparatus, taken along line A-A′ in FIG. 1.

FIG. 3 is a conceptual diagram of the substrate processing apparatus in FIG. 1.

FIG. 4 is a conceptual diagram of a substrate processing apparatus according to another example embodiment of the present disclosure.

### DETAILED DESCRIPTION

A substrate processing apparatus according to an example embodiment may include a process chamber, a substrate entrance formed on a sidewall of the process chamber, and a valve for opening and closing the substrate entrance. The valve may include a blade for opening and closing the substrate entrance, and a driving unit allowing the blade to ascend and descend. The blades may provide an internal side surface of the process chamber between a lower surface of the process chamber and the substrate entrance. That is, the blade may provide an internal side surface forming a part of the internal side surface of the chamber. Accordingly, the internal side surface of the blade and the internal side surface of the process chamber may be continuously connected to improve structural symmetry. The structural symmetry may provide symmetry of flow and exhaustion of a gas to improve process uniformity.

During a process, contaminants may be deposited on the internal side surface of the blade. As the blade ascend and descends, the contaminants may be desorbed therefrom to generate particles. When the particles adhere to the substrate in the process chamber, the particles may cause component defects.

In addition, when plasma is generated in the process chamber, the process chamber may be maintained at a predetermined temperature and electrically grounded. The blade may not be electrically connected to the process chamber and may be in contact with the process chamber with a sealing means, such as an O-ring, interposed therebetween. Accordingly, the blade may provide electrical characteristics, different from those of the process chamber, to provide locally different plasma characteristics.

Accordingly, there is a need to suppress the deposition of the contaminants on the blade and to control the electrical characteristics of the blade. The contaminants on the blade may be sputtered by incidence of plasma ions to be removed. A control electrode may be formed on the internal side surface of the blade, and DC power or RF power may be applied to the control electrode. When a positive DC voltage is applied to the control electrode, cations in plasma diffused in a reaction space may be repelled to suppress the deposition of the contaminants and to change local plasma characteristics. When a negative DC voltage is applied to the control electrode, cations in the plasma diffused in the reaction space may be attracted such that the contaminants are sputtered to suppress the deposition of the contaminants and to change the local plasma characteristics. When RF power is applied to the control electrode, additional plasma may be generated on a surface of the control electrode to sputter the contaminants and to change the local plasma characteristics.

When a susceptor is present in a center of the process chamber, the susceptor supplied with the RF power and a grounded gas injector may face each other and may form a main capacitor and the susceptor and a wall of the process chamber may form a parasitic capacitor. When the blade is placed on a sidewall of the process chamber, azimuthal asymmetry of the parasitic capacitor may occur. That is, a variation of parasitic impedance between the susceptor and the sidewall of the grounded process chamber occurs depending on an azimuthal angle. Such a variation of parasitic impedance may affect the RF current flowing through the parasitic capacitor. The RF current may affect a plasma density distribution to cause azimuthal non-uniformity of plasma density. To overcome the directional non-uniformity of the plasma density caused by the parasitic impedance, DC power or RF power may be applied to the control electrode disposed intentionally on the blade. For example, when the plasma density is locally low in a direction of the blade due to the parasitic impedance of the blade, or the like, a negative DC voltage may be applied to the control electrode. When the negative voltage is so low to the level of several volts, the control electrode charged with a negative DC voltage may attract or repel the cations to control the local plasma density non-uniformity.

On the other hand, when the plasma density is locally high in the direction of the blade due to the parasitic impedance of the blade, or the like, a positive voltage may be applied to the control electrode. The control electrode, charged with the positive voltage, may attract or repel the cations to control the local plasma density non-uniformity.

When the RF power is applied to the control electrode, the control electrode may operate as a new plasma source to control the plasma density non-uniformity.

According to an example embodiment, the blade may be grounded or connected to an impedance circuit. The impedance circuit may include LC circuits connected to each other in parallel, or LC circuits connected to each other in series. A capacitor of the impedance circuit may impede direct current flowing from the blade to a ground. In addition, the capacitor of the impedance circuit may pass RF current. An inductor of the impedance circuit may pass RF current having a phase opposite to a phase of the capacitor. Thus, the impedance circuit may change impedance between the blade and the ground to locally change plasma characteristics.

Hereinafter, embodiments of the present disclosure will be described below more fully with reference to accompanying drawings. The present disclosure may, however, be embodied in different forms and should not be constructed as limited to the embodiments set forth herein. Rather, these embodiments are provided so that this disclosure will be thorough and complete, and will fully convey the scope of the present invention to those skilled in the art.

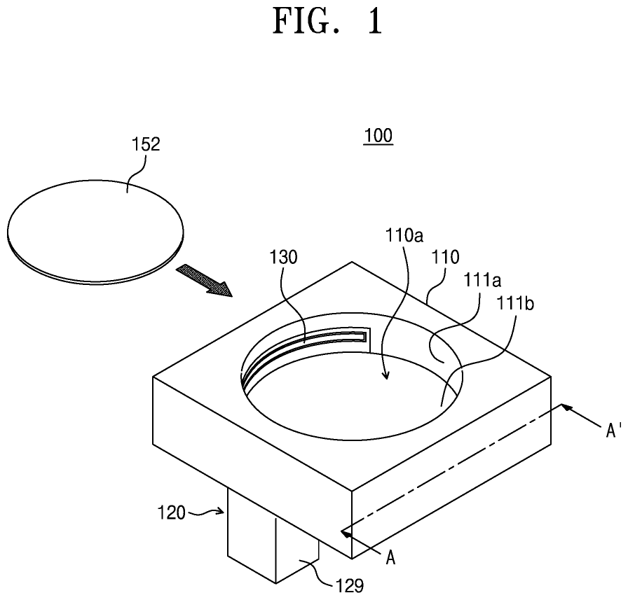

FIG. 1 is a perspective view of a substrate processing apparatus according to an example embodiment of the present disclosure.

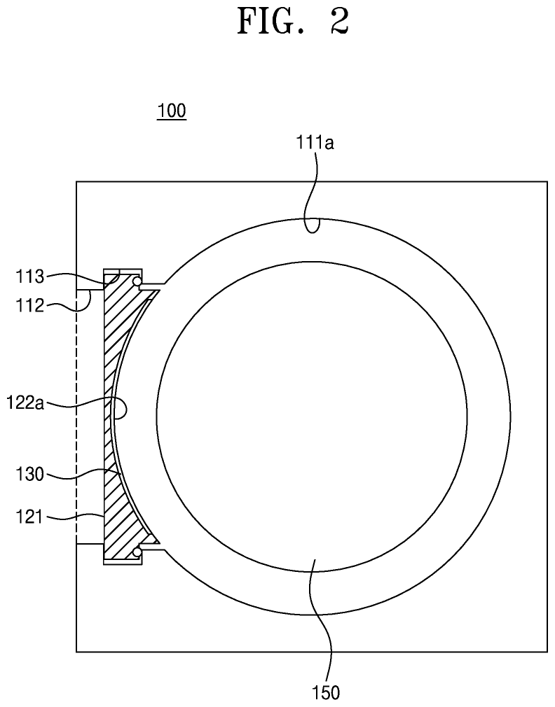

FIG. 2 is a cross-sectional view of the substrate processing apparatus, taken along line A-A′ in FIG. 1.

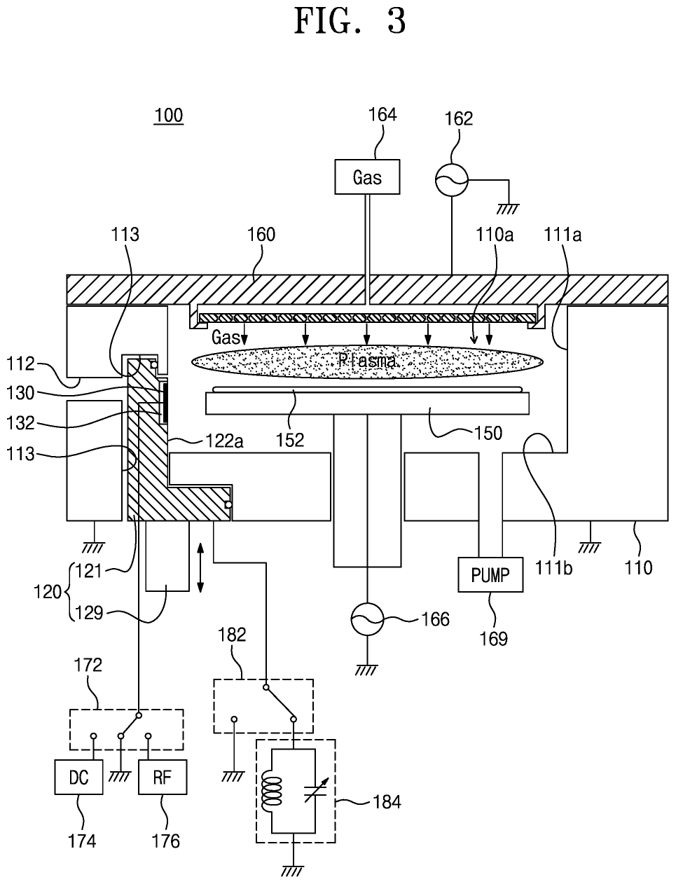

FIG. 3 is a conceptual diagram of the substrate processing apparatus in FIG. 1.

Referring to FIGS. 1 to 3, a substrate processing apparatus 100 may include a process chamber 110 providing a reaction space 110a therein and including a substrate entrance 112 through which a substrate 152 enters or exits, a susceptor 150 disposed inside the process chamber 110 and supporting the substrate 152, a gas injector 160 disposed on an opposing surface to inject a gas toward the substrate 152, a valve opening and closing the substrate entrance 112, and a control electrode formed on the valve.

The substrate processing apparatus 100 may perform a deposition process or an etching process.

The process chamber 110 may form a reaction space 110a with a substrate entrance 112 on at least one sidewall thereof. The process chamber 110 may have a cuboidal shape, and the reaction space 110a may have a cylindrical structure. The process chamber 110 may have a lower surface 111b and a sidewall 111a.

The gas injector 160 may be disposed on an open upper surface of the process chamber 110. The gas injector 160 may operate as a chamber lid. The gas injector 160 may be supplied with RF power to generate plasma. The process chamber 110 may be exhausted through a pump 169. The process chamber 110 may be electrically grounded.

The substrate entrance 112 may penetrate through the sidewall of the process chamber 110 to be connected to the reaction space 110a. The substrate entrance 112 may be continuously connected to an opening 113 in which a blade 121 is disposed. The blade 121 may open and close the substrate entrance 112 while ascending and descending. The substrate entrance 112 may provide structural asymmetry of the process chamber 110.

The gas injector 160 may include a plurality of nozzles and may inject a gas, provided from a gas supply unit 164, into the reaction space 110a. The gas injector 160 may receive RF power externally to generate plasma. A first RF power supply 162 may supply RF power to the gas injector 160 through a first impedance matching network (not illustrate).

The susceptor 150 may include a heating unit (not illustrated) on which the substrate 152 may be mounted and heated to a predetermined temperature. The susceptor 150 may ascend and descend vertically. The susceptor 150 may include an electrostatic chuck (not illustrated) for fixing the substrate 152. In addition, the susceptor 150 may receive RF power externally to generate plasma and may adjust energy incident on the substrate 152. The second RF power supply 166 may supply RF power to the susceptor 150 through a second impedance matching network (not illustrated).

The valve 120 may be disposed on an internal side surface of the process chamber 110 to open and close the substrate entrance 112. The valve 120 may suppress structural asymmetry of the process chamber 110.

The valve 120 may include a blade 121, opening and closing the substrate entrance 112, and a driving unit 129 allowing the blade 121 to ascend and descend. The driving unit 129 may be connected to the sidewall or a lower surface of the process chamber 110 to be supported by a separate housing. The blade 121 may be inserted into an opening 113, formed in the sidewall of the process chamber 110, to provide the internal side surface 122a forming a part of the internal side surface of the process chamber 110.

The blade 121 may be grounded or connected to an impedance circuit 184. The impedance circuit 184 may include LC circuits connected to each other in parallel, or LC circuits connected to each other in series.

When the impedance circuit 184 includes a capacitor and an inductor and the capacitor and the inductor are connected to each other in series, impedance of the impedance circuit 184 is a minimum at a driving frequency and the impedance circuit 184 may constitute a resonance circuit. The impedance circuit 184 having the minimum impedance may increase RF current flowing through the blade 121, and the blade may be stably grounded to stabilize the plasma. That is, the blade 121 may be controlled by the impedance circuit 184 to have the same electrical characteristics as an internal wall of the process chamber 110. The impedance circuit 184 may be an LC series resonant circuit such that the blade 121 provides the same electrical characteristics as in the state in which the internal wall of the process chamber is uncontaminated.

On the other hand, when the impedance circuit 184 includes a capacitor and an inductor and the capacitor and the inductor are connected to each other in parallel, impedance of the impedance circuit 184 is a maximum at a driving frequency and the impedance circuit 184 may constitute a resonance circuit. Accordingly, the impedance circuit 184 may increase impedance between the blade 121 and the ground to decrease the RF current flowing through the blade 121, so that a large amount of RF current may flow through the wall of the process chamber 110. As a result, the plasma characteristics may be locally changed. The impedance circuit 184 may be an LC parallel resonant circuit such that the blade 121 provides the same electrical characteristics as in the state in which the internal wall of the process chamber is heavily contaminated.

A first switch 182 may selectively connected to the ground and the first impedance circuit 184. The capacitor of the impedance circuit 184 may vary, and may adjust RF current flowing from the blade 121 to the ground. The impedance circuit 184 may change the impedance between the ground and the blade 121 to change local plasma characteristics.

The blade 121 may not be electrically connected to the process chamber 110 and may be in contact with the process chamber 110 with a sealing means, such as an O-ring, interposed therebetween. Accordingly, the blade 121 may provide electrical characteristics, different from those of the process chamber 110, to provide locally different plasma characteristics. The blade 121 may be grounded or connected to a ground through the impedance circuit 184 to control plasma characteristics by the blade 121.

The control electrode 130 may be formed on the internal side surface 122a of the blade 121. The control electrode 130 may be arranged via the blade 121 and an insulating layer 132 for insulation. The control electrode 130 may be formed in an azimuthal direction of the internal side surface 122a to have a circular arc band shape. The control electrode 130 may be disposed adjacent to an upper surface of the opening 113 to interact with the plasma in the reaction space. An area of the control electrode 130 may be smaller than an area of the wall of the process chamber 110 by several tenths or less. In this case, a voltage applied to the control electrode may change the local plasma density distribution with almost no effect on a plasma potential.

The DC power supply 174, the ground, or the RF power supply 176 may be selectively connected to the control electrode 130 through a second switch 172. The DC power source 174 may be a positive DC power supply or a negative DC power supply.

During a process, contaminants may be deposited on the internal side surface of the blade 121. The contaminants may be desorbed as the blade 121 ascends and descends, resulting in generation of particles. When the particles adhere to the substrate in the process chamber, the particles may cause element defects.

Accordingly, there is a need to suppress deposition of the contaminants on the blade 121 and to control the electrical characteristics by the blade 121.

DC power or RF power may be applied to the control electrode 130. When a positive DC voltage is applied to the control electrode 130, cations in the plasma diffused in the reaction space 110a may be repelled to suppress the deposition of the contaminants or to change local plasma characteristics. When a negative DC voltage is applied to the control electrode 130, cations in the plasma diffused in the reaction space 110a may attracted such that the contaminants are sputtered to suppress the deposition of the contaminants or to change local plasma characteristics. When RF power is applied to the control electrode 130, separate plasma may be generated on the surface of the control electrode 130 to sputter the contaminants or to change the local plasma characteristics. As a result, azimuthal symmetry of the plasma may be improved and substrate processing uniformity may be increased.

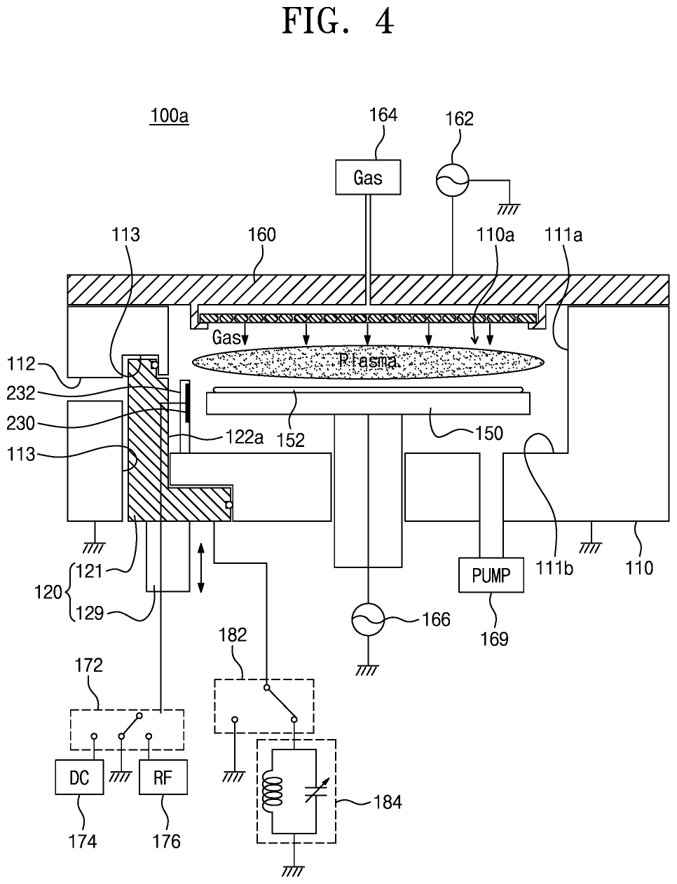

FIG. 4 is a conceptual diagram of a substrate processing apparatus according to another example embodiment of the present disclosure.

Referring to FIG. 4, a substrate processing apparatus 100a may include a process chamber 110 providing a reaction space 110a therein, a susceptor 150 disposed inside the process chamber 110 and supporting a substrate 152, a gas injector 160 disposed on an opposing surface of the susceptor 150 to inject a gas toward the substrate 152, and a control electrode 230 formed locally outside the susceptor 150 or on an internal side surface forming a part of the internal side surface of the process chamber 110.

The control electrode 230 may be formed on a separate control electrode support unit 232, rather than an internal side surface 122a of the blade 121, and may be locally disposed outside the susceptor 150. The control electrode 230 may have the same shape as described in FIG. 1. The control electrode 230 may be locally disposed to view the blade 121. The control electrode support unit 232 may be disposed to rotate in an azimuthal direction with respect to a rotation means (not illustrated) such that the substrate 152 enters or exits, and the control electrode support unit 232 may then rotate again for performing a process to be aligned to view the blade 121.

As described above, a substrate processing apparatus according to an example embodiment may provide a uniform process environment to an entire reaction space of a chamber using a control electrode, and may suppress generation of particles.

In addition, a valve providing an internal curved surface forming a part of the internal side surface of the chamber may be inserted and connected to an impedance circuit to change electrical characteristics. As a result, the substrate processing apparatus may control local process non-uniformity of a substrate.

Although the present disclosure and its advantages have been described in detail, it should be understood that various changes, substitutions and alterations can be made herein without departing from the spirit and scope of the disclosure as defined by the following claims.

What is claimed is:

1. A substrate processing apparatus comprising:
a process chamber providing a reaction space therein and including a substrate entrance through which a substrate enters or exits;
a susceptor disposed inside the process chamber and supporting the substrate;
a gas injector disposed on an opposing surface to inject a gas toward the substrate;
a valve opening and closing the substrate entrance; and
a control electrode formed on the valve.

2. The substrate processing apparatus as set forth in claim 1, wherein the control electrode is vertically driven.

3. The substrate processing apparatus as set forth in claim 1, wherein the valve comprises:
a blade opening and closing the substrate entrance and having an internal surface forming a part of the internal side surface of the process chamber; and
a driving unit allowing the blade to ascend and descend, and
wherein the control electrode is formed on the blade.

4. The substrate processing apparatus as set forth in claim 3, wherein the blade is selectively grounded or connected to an impedance circuit by a first switch.

5. The substrate processing apparatus as set forth in claim 4, wherein the impedance circuit includes LC circuits connected to each other in parallel, or LC circuits connected to each other in series, and
a capacitor constituting each of the LC circuits is variable.

6. The substrate processing apparatus as set forth in claim 1, wherein the control electrode is connected to a power supply unit.

7. The substrate processing apparatus as set forth in claim 6, wherein the power supply unit includes at least one of a positive DC power supply, a negative DC power supply, and an RF power supply.

8. The substrate processing apparatus as set forth in claim 7, further comprising:
a second switch configured to connect the power supply unit or a ground and the control electrode to each other,
wherein the second switch selectively connected to one of the positive DC power supply, the negative DC power supply, and the RF power supply.

9. A substrate processing apparatus comprising:
a process chamber providing a reaction space therein;
a susceptor disposed inside the process chamber and supporting a substrate;
a gas injector disposed on an opposing surface of the susceptor to inject a gas toward the substrate; and
a valve providing an internal side surface forming a part of the internal side surface of the process chamber and opening and closing a substrate entrance of the process chamber,
wherein the valve comprises:
a blade opening and closing the substrate entrance and having the internal side surface forming a part of the internal side surface of the process chamber; and
a driving unit allowing the blade to ascend and descent, and
wherein the blade is selectively grounded or connected to an impedance circuit by a switch.
